(19) United States
(12) Patent Application Publication
(10) Pub. No.: US 2019/0097116 A1
(43) Pub. Date: Mar. 28, 2019

(54) METHOD FOR PRODUCING A THERMOELECTRIC CONVERTER

(71) Applicant: Mahle International GmbH, Stuttgart (DE)

(72) Inventors: Hans-Heinrich Angermann, Stuttgart (DE); Juergen Gruenwald, Ludwigsburg (DE); Michael Moser, Ellwangen (DE); Thomas Pfadler, Stuttgart (DE)

(21) Appl. No.: 16/141,960

(22) Filed: Sep. 25, 2018

(30) Foreign Application Priority Data
Sep. 26, 2017 (DE) 102017217123.5

(51) Int. Cl. H01L 35/34; H01L 35/32; H01L 35/08

(52) U.S. Cl. CPC H01L 35/34; H01L 35/08; H01L 35/32

(57) ABSTRACT

A method for producing a thermoelectric converter may include equipping a substrate top side of an electrically conductive substrate with a first thermoelectrically active material and applying an electrically conductive upper conducting layer thereon, and equipping a substrate bottom side with a second thermoelectrically active material and applying an electrically conductive lower conducting layer thereon. The method may further include introducing a plurality of upper receptacles on the substrate top side and a plurality of lower receptacles on the substrate bottom side to produce an intermediate product. The method may additionally include applying an electrically conductive upper cover layer to an intermediate product top side and an electrically conductive lower cover layer to an intermediate product bottom side. The method may also include introducing a plurality of upper clearances on the intermediate product top side and a plurality of bottom clearances on the intermediate product bottom side.

### CROSS-REFERENCE TO RELATED APPLICATIONS

This application claims priority to German Patent Application No. DE 10 2017 217 123.5, filed on Sep. 26, 2017, the contents of which are hereby incorporated by reference in its entirety.

### TECHNICAL FIELD

The present invention relates to a method for producing a thermoelectric converter by providing an electrically conductive substrate and equipping the substrate with thermoelectrically active material. The invention, furthermore, relates to a thermoelectric converter produced in such a manner.

### BACKGROUND

The use of thermoelectric converters, which are capable in particular by applying an electric voltage to generate a temperature difference and vice versa becomes increasingly important. Such converters can be employed for example for temperature-controlling various items and/or fluids, in particular in an air-conditioning system, for example of a vehicle. With the increasing importance, the relevance of the production of such converters also increases. It is desirable to produce the converters cost-effectively and/or variably and/or with a high quality.

For producing a thermoelectric converter, thermoelectrically active elements are usually provided, which are each serially interconnected by separate conductor elements, in particular in the form of metal plates. This type of production of thermoelectric converters therefore requires many individual method steps rendering the production complicated and thus expensive. In addition, for producing thermoelectric converters which are distinct from one another, adapted conductor elements and thermoelectrically active elements have to be provided in each case as a result of which the production again becomes elaborate and expensive.

### SUMMARY

The present invention therefore deals with the object of stating improved or at least other embodiments for a method for producing a thermoelectric converter and for such a thermoelectric converter, which are characterized in particular by a simplified and/or cost-effective production of the converter.

According to the invention, this object is solved through the subject matter of the independent claim(s). Advantageous embodiments are subject of the dependent claim(s).

The present invention is based on the general idea of producing a thermoelectric converter by equipping an electrically conductive substrate with thermoelectrically active material and introducing suitable receptacles and clearances in the substrate equipped with thermoelectrically active material. In this way, the arranging of elements of thermoelectrically active material spaced from one another and the electrical contacting of these elements can be dispensed with, so that the production of the thermoelectric converter can be carried out in a simplified manner and thus more cost-effectively. In addition, differently designed thermoelectric converters can be produced by adapted equipping of the electrically conductive substrate with thermoelectrically active material and/or adapted introduction of the receptacles or clearances in a simple manner and based on the same principle, so that an increased variability for producing different thermoelectric converters can be achieved.

According to the inventive idea, the electrically conductive substrate is initially provided, which preferentially is flat or plate-like, i.e. in particular is formed as a plate. Sides of the substrate facing away from one another are then equipped with thermoelectrically active material. Here, a substrate top side of the substrate is equipped with a first thermoelectrically active material and a substrate bottom side facing away from the substrate top side of the substrate equipped with a second thermoelectrically active material. Following this, a conducting layer of an thermoelectrically conductive material is applied to the respective thermoelectrically active material. This means that on the first thermoelectrically active material an electrically conductive upper conducting layer and on the second thermoelectrically active material an electrically conductive lower conducting layer is applied. When the respective conducting layer is applied, suitable receptacles are introduced on the substrate top side or substrate bottom side in order to produce material sections of the thermoelectrically active material that are spaced from one another in a transverse direction. Here, upper receptacles extending on the substrate top side in a longitudinal direction extending transversely to the transverse direction and which are spaced from one another in the transverse direction are introduced and on the substrate bottom side lower receptacles running in the longitudinal direction and which are spaced from one another in the transverse direction. Following the introduction of the receptacles, an intermediate product is produced which is subsequently processed to form the thermoelectric converter. Here, the receptacles are introduced in such a manner that the upper receptacles overlap in the transverse direction in each case in an overlap section extending in the transverse direction and extending in particular in the longitudinal direction with at least one of the lower receptacles that are adjacent in the transverse direction. In other words, the upper receptacles are spaced from one another in the transverse direction but not spaced from the adjacent lower receptacles. Similar applies analogously to the lower receptacles. Here, the receptacles remove in their associated region in each case the associated thermoelectrically active material, so that adjacent material sections are created in the transverse direction. Thus, the upper receptacles remove the first thermoelectrically active material in their respective associated region so that in the transverse direction adjacent upper material sections are created. Here, because of the abovementioned overlapping arrangement of the receptacles, the upper material sections are arranged in the transverse direction alternately and spaced from one another or offset relative to one another. When the receptacles are introduced, an electrically conductive cover layer is applied to the respective associated side. This means that an electrically conductive upper cover layer is applied to an intermediate product top side of the intermediate product, which is adjacent to the substrate top side or offset relative to the same. Analogously to this, an electrically conductive lower cover layer is applied to an intermediate product bottom side of the intermediate product facing away from the intermediate product top side. The respective cover layer is preferentially applied in such a manner that the previously introduced receptacles are at least partly filled with the cover layer. When the respective cover layer is applied, suitable clearances are introduced into the respective associated side in order to produce the thermoelectric converter. Here, upper clearances extending in the longitudinal direction and which are spaced from one another in the transverse direction are introduced on the intermediate product top side. Analogously to this, bottom clearances which extend in the longitudinal direction and are spaced from one another in the transverse direction are introduced on the intermediate product bottom side, wherein the respective clearance is introduced in one of the overlap sections. Introducing the clearances is effected in such a manner that they remove the associated cover layer in each case the associated region and enter the substrate in order to form a hollow space separating the material sections that are adjacent in the transverse direction. This means that the upper clearances are introduced in such a manner that they remove the upper cover layer in each case in the associated region and enter the substrate so far that the material sections that are adjacent in the transverse direction, i.e. in each case a first material section and a second material section, are separated from one another by a hollow space but are electrically connected. Analogously to this, the lower recesses are introduced in such a manner that they in each case remove the lower cover layer in the associated region and enter the substrate and in each case form a hollow space separating the material sections that are adjacent in the transverse direction, i.e. a second material section and a first material section, but which are electrically contacted with one another.

The hollow spaces are each practically formed in such a manner that material sections that are adjacent in the transverse direction are electrically and mechanically connected in series. This means that material sections that are adjacent in the transverse direction form an electrical and mechanical series arrangement.

It is to be understood that the method steps stated above can also be performed in other sequences provided they lead to the same result. It is possible, for example, to equip the substrate top side with the first thermoelectrically active material, to provide the same with the upper conducting layer, introduce the upper receptacles, apply the upper cover layer and introduce the upper clearances before the corresponding steps are performed on the substrate bottom side.

Basically, the respective conducting layer can be configured in any way. In particular, the respective line layer can be in multiple layers, wherein the individual layers can be applied one after the other.

The respective conducting layer is preferentially configured in such a manner that it results in an improved adhesion of the subsequently applied associated cover layer. Accordingly, the conducting layer can also be referred to as contact layer. For this purpose, the respective conducting layer can at least partly consist of a mixture of different components. This means in particular that individual layers of the conducting layer can consist of a mixture or comprise a mixture.

The respective thermoelectrically active material is preferentially equipped in such a manner that the associated side of the substrate is entirely equipped with the thermoelectrically active material. On the one hand, the entire substrate is used for producing the thermoelectric converter. On the other hand, subsequent steps for producing the converter can be easily performed. Analogously to this it is preferred when the respective conducting layer and/or the respective cover layer entirely cover/s the associated side.

Preferred are embodiments, with which the upper receptacles are introduced in such a manner that they each remove the upper conducting layer and the first electrically active material in the associated region, so that the upper material sections spaced in the transverse direction are created. Analogously to this it is preferred when the lower receptacles are introduced in such a manner that they each remove the lower conducting layer and the second thermoelectrically active material in the associated region in order to produce the lower material sections that are spaced in the transverse direction. It is advantageous, furthermore, to introduce the upper clearances in such a manner that they each remove the upper cover layer in the associated region, enter the substrate and each form one of the hollow spaces separating the material sections that are adjacent in the transverse direction. It is particularly preferred when the upper clearances are introduced in such a manner that they enter the cover layer located opposite, i.e. the lower cover layer however without removing the same. By way of this, undesirable electric currents between adjacent material sections are prevented so that the efficiency of the thermoelectric converter is improved. An improved thermal separation between adjacent material sections is additionally effected by way of this, so that the efficiency of the thermoelectric converter is again improved. It is preferred, furthermore, when the bottom clearances are introduced in such a manner that they each remove the lower cover layer in the associated region, enter the substrate and each form one of the hollow spaces separating the material sections that are adjacent in the transverse direction. In order to achieve and/or further increase the aforementioned advantages, the bottom clearances should preferably enter the cover layer located opposite, i.e. the upper cover layer, however without removing the same.

Embodiments in which the substrate following the introduction of the clearances by the introduction of at least one cut extending obliquely to the longitudinal direction is divided into at least two separate parts prove to be advantageous, wherein the respective part forms a thermoelectric converter. This means that the previously produced thermoelectric converter is separated into multiple parts in such a manner that the respective part again forms a thermoelectric converter.

Prior to the equipping of the turned-away substrate side of the substrate with the thermoelectrically active material it is conceivable to provide at least one of the conducting layers with an electrically insulating insulating layer. By way of this it is prevented in particular that the conducting layer, to which the insulating layer is applied, is provided with the thermoelectrically active material which has to be applied to the turned-away side. It is conceivable, for example, to provide the upper conducting layer, before equipping the substrate bottom side with the second thermoelectrically active material with an upper electrically insulating insulating layer in order to prevent in particular that during the equipping of the substrate with the second thermoelectrically active material the second thermoelectrically active material reaches the upper conducting layer. By way of this, undesirable currents between the thermoelectrically active materials are thus prevented and consequently a quality and/or efficiency of the thermoelectric converter improved. Similar applies when the lower conducting layer prior to equipping the substrate top side with the first thermoelectrically active material is provided with an electrically insulating bottom insulating layer.

Practically, the respective insulating layer is removed before the coating of the associated side with the cover layer. By way of this, a continuous electrical connection between the conducting layer and the associated cover layer is created, so that undesirable electrical contacting of adjacent material sections is improved.

The respective thermoelectrically active material can be applied to the associated substrate side generally in any way. Here it is preferred when the thermoelectrically active material is coated onto the associated substrate side.

Considered advantageous are embodiments, with which at least one of the thermoelectrically active material is applied to the associated substrate side in particular by way of physical vapour deposition (PVD). Because of this, a large-area application of the respective thermoelectrically active material with low contaminations and in a high quality is possible.

It is advantageous when at least one of the conducting layers and/or at least one of the cover layers is applied by a vacuum-based deposition method, in particular deposited. By way of this, the relevant conducting layer or cover layer can be applied over a large area and/or with low contamination and/or in a high quality. When for applying the thermoelectrically active materials and/or the conducting layers and/or the cover layers, the same deposition method is employed, producing the thermoelectric converter can be carried out particularly cost-effectively and/or with a particularly high quality.

It is conceivable to provide at least one of the conducting layers and/or one of the cover layers with a protective layer for preventing or at least reducing the oxidation of the conducting layer or the cover layer. The protective layer, which can also be referred to as oxidation protection layer, can consist in particular of a precious metal, for example gold or comprise such a metal. The protective layer is preferentially thin compared with the remaining applied layers, in order to achieve in particular an improved efficiency of the converter or reduce the efficiency by as little as possible. When the protective layer is applied to the conducting layer, the protective layer can be removed prior to applying the associated cover layer. Generally, this results in an improved adhesion of the cover layer to the conducting layer. However it is also conceivable to apply the cover layer to the protective layer in the region of the conducting layer.

It is obviously conceivable to also perform other method steps between the stated method steps, such as for example a cleaning, an attachment and the like.

It is to be understood that besides the method for producing the thermoelectric converter such a converter also forms part of the scope of this invention.

Here, the converter can be employed in particular as a Peltier element, which when energised with an electric current, exchanges heat between at least two regions, in particular pumps heat.

A possible use of the thermoelectric converter, in particular of the Peltier element, is in an air-conditioning system for example of a vehicle.

Further important features and advantages of the invention are obtained from the subclaims, from the drawings and from the associated figure description by way of the drawings.

It is to be understood that the features mentioned above and still to be explained in the following cannot only be used in the respective combination stated but also in other combinations or by themselves without leaving the scope of the present invention.

### BRIEF DESCRIPTION OF THE DRAWINGS

It shows, in each case schematically,

FIGS. 1 to 6 show a lateral view with different method steps for producing a thermoelectric converter,

FIG. 7 shows a plan view of the converter with another exemplary embodiment,

FIG. 8 shows a lateral view of thermoelectric converters.

### DETAILED DESCRIPTION

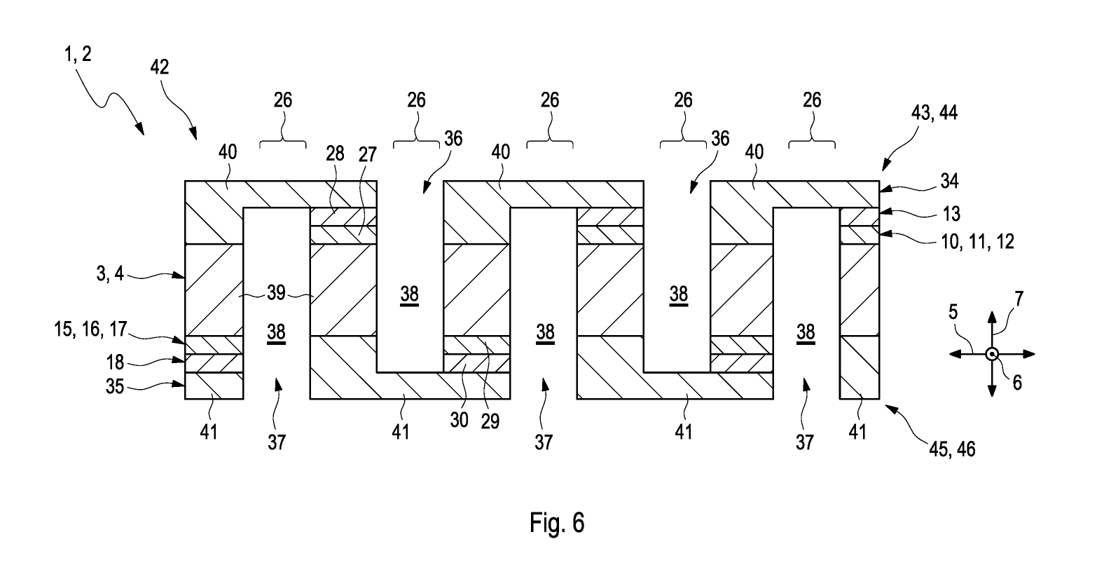

For producing a thermoelectric converter 1, in particular a Peltier element 2, as is visible for example in FIG. 6, an electrically conductive substrate 3 is initially provided, such as is shown in FIG. 1. The substrate 3 in FIG. 1 is flat and plate-like and thus designed as a plate 4. The electrically conductive substrate 3 is preferably produced from a metal or a metal-containing alloy, for example from aluminium. The substrate 3 extends in a transverse direction 5 and a longitudinal direction 6 extending transversely to the transverse direction 5. In a height direction 7 extending transversely to the transverse direction 5 and transversely to the longitudinal direction 6, the substrate 3 comprises a substrate top side 8 and a substrate bottom side 9 facing away from the substrate top side 8.

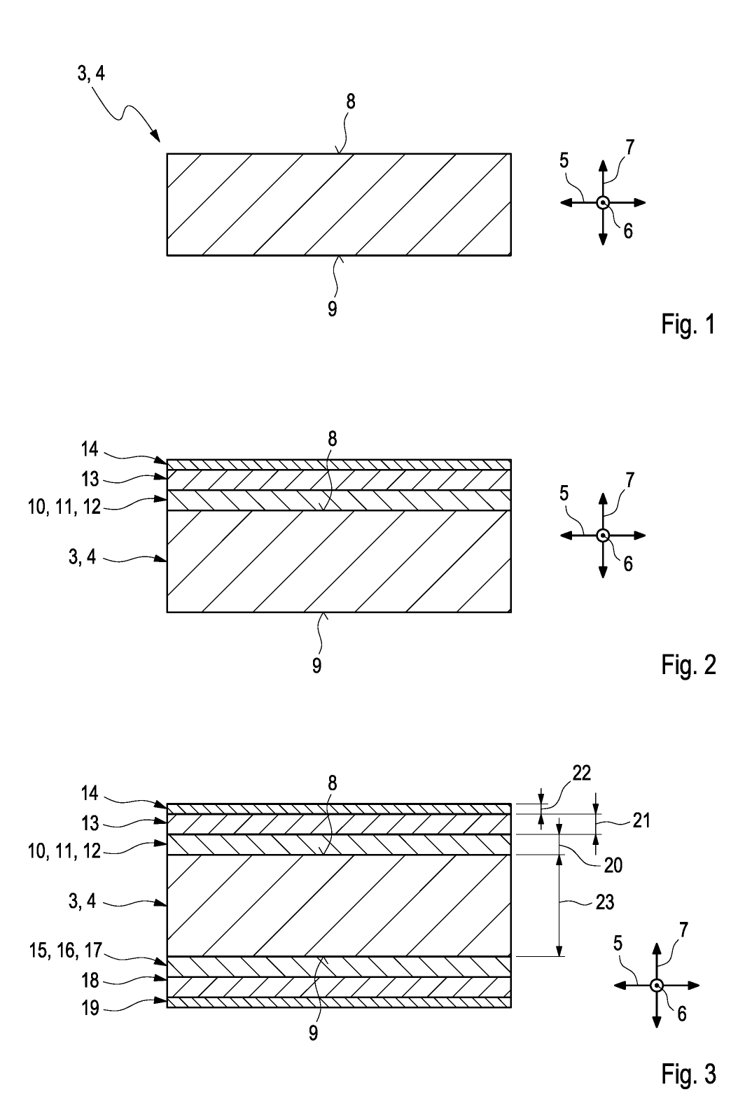

According to FIG. 2, the substrate top side 8 is equipped with a thermoelectrically active material 10, in particular a semiconductor 11, for example an n-doped N-semiconductor 12. In addition, an electrically conductive conducting layer 13 or contact layer 13, in the following also referred to as upper conducting layer 13 or upper contact layer 13, is applied to the first thermoelectrically active material 10. The first thermoelectrically active material 10 is closed on the substrate top side 8 and applied in such a manner that the entire substrate top side 8 is covered with the first thermoelectrically active material 10. Analogously to this, the upper conducting layer 13 is closed and applied to the first thermoelectric material 10 in such a manner that the side of the first thermoelectrically active material 10 facing away from the substrate top side 8 is entirely covered by the upper conducting layer 13. In the shown example, an optional protective layer 14 is additionally applied to the upper conducting layer 13, which is likewise closed and which is entirely covered by the first thermoelectrically active material 10 on the turned-away side of the upper conducting layer 13. Here, the protective layer 14 serves for protecting the conducting layer 13 or contact layer 13 from oxidation and can consist of a precious metal, for example gold or comprise a precious metal. FIG. 2 shows a state in which the first thermoelectrically active material 10, the upper conducting layer 13 as well as the protective layer 14, in the following referred to as upper protective layer 14, are applied.

According to FIG. 3, the substrate bottom side 9 is subsequently equipped with a second thermoelectrically active material 15, in particular a second semiconductor 16, for example a p-doped P-semiconductor 17. In addition, an electrically conductive conducting layer 18 or contact layer 18, in the following also referred to as lower conducting layer 18 or lower contact layer 18 is applied to the second thermoelectrically active material 15. The second thermoelectrically active material 15 is applied in such a manner that the entire substrate bottom side 9 is covered with the second thermoelectrically active material 15 and the second thermoelectrically active material 15 forms a closed layer. Analogously to this, the lower conducting layer 18 is applied to the entire side of the second thermoelectrically active material 15 facing away from the substrate bottom side 9 in such a manner that a closed layer of the lower conducting layer 18 forms on the second thermoelectrically active material 15. In the shown example, an optional, electrical protective layer 19 is additionally applied to the lower conducting layer 18, which in the following is also referred to as bottom protective layer 19, wherein the bottom protective layer 19 entirely covers the side of the lower conducting layer 18 facing away from the second thermoelectrically active material 15. Analogously to the upper protective layer 14, the bottom protective layer 19 serves for the purpose of protecting the lower conducting layer 18 or contact layer 18 from oxidation and can consist of a previous metal, for example gold, or comprise a precious metal.

The thermoelectrically active materials 10, 15, the conducting layers 13, 18 and the protective layers 14, 19 are each applied with a substantially constant thickness extending in the height direction 7. A material thickness 20 of the respective thermoelectrically active material 10, 15 can be between 10 μm and 100 μm. A conductor thickness 21 of the respective conducting layer 13, 18 can be between 10 μm and 100 μm. The respective protective layer 14, 19 preferentially has a protective layer thickness 22, which is smaller than the associated material thickness 20 and/or conductor thickness 21. The protective layer thickness 22 can be for example between 10 nm and 100 nm. Compared with this, the substrate 3 has a substrate thickness 23 that is greater than the material thicknesses 20, the conductor thicknesses 21 and the protective layer thicknesses 22, for example between 0.1 mm and 1 mm. The respective conducting layer 13, 18 is preferably produced from a metal or from a metal-containing material, in particular from aluminium or an aluminium alloy.

The respective thermoelectrically active material 10, 15, the respective conducting layer 13, 18 and the respective protector layer 14, 19 are advantageously applied with the help of a vacuum-based deposition method, in particular by physical gas phase depositions.

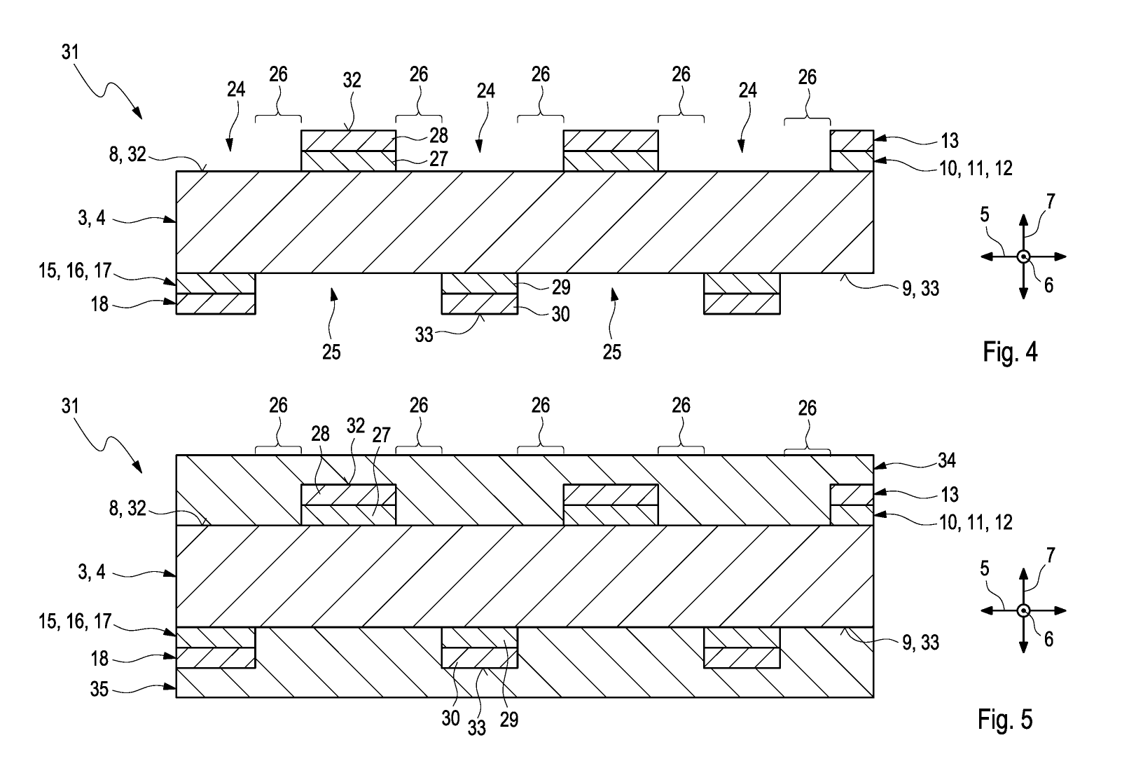

Following the application of the thermoelectrically active material 10, 15 located opposite and/or after the method steps explained in the following, the respective layer 14, 19 is removed. As shown in FIG. 4, upper receptacles 24 and lower receptacles 25 are subsequently introduced on the substrate top side 8 and on the substrate bottom side 9 respectively. The upper receptacles 24 and the lower receptacles 25 each extend in the longitudinal direction 6 and, in the shown example, are dimensioned identically in the transverse direction 5. The upper receptacles 24 are spaced from one another in the transverse direction 5. Similar applies to the lower receptacles 25, which are spaced from one another in the transverse direction 5. Here, the upper receptacles 24 and the lower receptacles 25 are introduced offset from one another in such a manner that the upper receptacles 24 in the transverse direction 5 overlap in each case with one of the lower receptacles 25 that are adjacent in the transverse direction 5 in an overlapping section 26 extending in the transverse direction and are spaced in the height direction 7. Here, the upper receptacles 24 are introduced in such a manner that in the respective associated region, they remove the upper conducting layer 13 and the first thermoelectrically active material 10, but not the substrate 3 in the shown example. Similar applies to the lower receptacles 25 which, in each case in the associated region, remove the lower conducting layer 18 and the second thermoelectrically active material 15, but not the substrate 3 in the shown example. Thus, upper material sections 27 of the first thermoelectrically active material 10 as well as upper conducting sections 28 of the upper conducting layer 13, which are separated from one another in the transverse direction 5, are created on the substrate top side 8. On the substrate bottom side 9, lower material sections 29 of the second thermoelectrically active material 15 are created, which are spaced from one another in the transverse direction 5, and lower conducting sections 30 of the second conducting layer 18, which are spaced from one another in the transverse direction 5. Here, the upper material sections 27 and conducting sections 28 are arranged offset in the transverse direction 5 regarding the lower material sections 29 and conducting sections 30. In the shown example, the receptacles 24, 25 additionally extend in the height direction 7, so that the upper material sections 27 and conducting sections 28 are arranged in the transverse direction 5 equidistantly from one another and from the lower material sections 29 and conducting sections 30 in each case. Following the introduction of the receptacles 24, 25, an intermediate product 31 is produced, which, analogously to the substrate 3, comprises an intermediate product top side 32 and an intermediate product bottom side 33 facing away from the intermediate product top side 32. The intermediate product 31 is subsequently processed to form the thermoelectric converter 1.

To this end, as shown in FIG. 5, an electrically conductive upper cover layer 34 and an electrically conductive lower cover layer 35 is initially applied to the intermediate product top side 32 and to the intermediate product bottom side 33 respectively. The respective cover layer 34, 35 is applied in such a manner that the previously introduced receptacles 24, 25 are filled up with the cover layer 34, 35 and the conducting sections 28, 30 are covered by the associated cover layer 34, 35. In the shown example, the respective cover layer 34, 35 is applied in such a manner that on the respective associated side a closed, in particular flat cover layer 34, 35 is formed.

As shown in FIG. 6, upper clearances 36 and bottom clearances 37 are subsequently introduced on the intermediate product top side 32 and on the intermediate product bottom side 33 respectively, in order to produce the thermoelectric converter, in particular the Peltier element 2. Here, the clearances 36, 37 extend in the longitudinal direction 6. In addition, the upper clearances 36 are spaced from one another in the transverse direction 5. Furthermore, the bottom clearances 37 are spaced from one another in the transverse direction 5. The upper clearances 36 and the bottom clearances 37 are alternately introduced in the transverse direction 5, wherein the respective clearance 36, 37 is introduced in one of the overlapping sections 26, so that the upper clearances 36 and the bottom clearances 37 are spaced from one another in the transverse direction 5. In the shown example, the clearances 36, 37 are dimensioned larger in the transverse direction 5 than the associated overlapping sections 26 and extend each in the height direction 7. Here, the upper clearances 36 are introduced in such a manner that they in each case remove the upper cover layer 34 in the associated region and enter the substrate 3, wherein in the shown example they remove the substrate 3 in the associated region and enter the lower cover layer 35 without, however, entirely removing the same. Since the upper clearances 36 are larger in the transverse direction 5 than the respective associated overlapping section 26, the respective associated lower material section 29 and lower conducting section 30 are additionally partly removed in the associated region in the transverse direction 5. The bottom clearances 37 are introduced in such a manner that in the associated region they remove the lower cover layer 35 in each case and enter the substrate 3, wherein in the shown example the substrate 3 in the associated region is removed. Since the bottom clearances 37 are larger in the transverse direction 5 than the respective associated overlapping section 26, the upper material section 27 and upper conducting section 28 each arranged in the associated region are partly removed in the transverse direction 5. In addition, the respective bottom clearance 27 enters the upper cover layer 34 in the associated region, however without entirely removing the same. The respective clearance 36, 37 forms a hollow space 38 separating the material sections 27, 29 that are adjacent in the transverse direction 5. By way of this, substrate sections 39 of the substrate 3, upper cover sections 40 of the upper cover layer 34 that are spaced from one another in the transverse direction as well as lower cover layers 41 of the lower cover layer 35 that are spaced from one another in the transverse direction 5 are created in addition to the material sections 27, 29 that are reduced in size in the transverse direction 5 and conducting sections 28, 30 that are spaced from one another in the transverse direction 5. Thus, an electrical and series arrangement 42 of the material sections 27, 29 are created, which in the arrangement 42 are arranged alternately. In the arrangement 42, material sections 27, 29 following one another are each electrically and mechanically connected to one another via a substrate section 39, a cover section 40, 41 and a conducting section 28, 30.

When the converter 1, in particular the Peltier element 2, is energised, a first thermal side 43, for example a cold side, materialises in the region of the upper cover sections 40, and a second thermal side 45, for example a warm side 46, of the converter 1 or of the Peltier element 2 in the region of the lower cover sections 41.

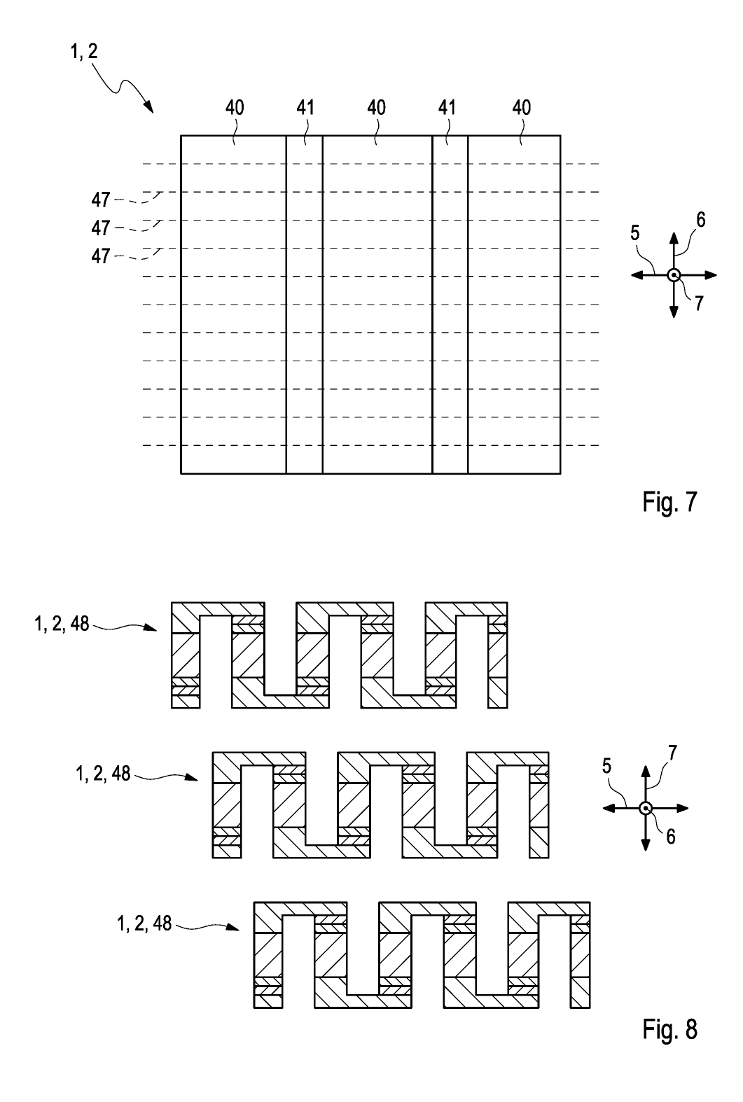

FIG. 7 shows a plan view of the converter 1 shown in FIG. 6. The shown converter 1, in particular the Peltier element 2, can be divided, as indicated with dashed lines, into multiple parts 48 shown in FIG. 8 by cuts 47 extending inclined relative to the longitudinal direction 6, in particular in the transverse direction 5, wherein the respective part 48 again forms a thermoelectric converter 1, in particular a Peltier element 2, which viewed laterally or in the transverse direction 5 corresponds to the converter 1 from FIG. 6, but is dimensioned smaller in the longitudinal direction 6.

1. A method for producing a thermoelectric converter, comprising:
equipping a substrate top side of an electrically conductive substrate with a first thermoelectrically active material;
applying an electrically conductive upper conducting layer to the first thermoelectrically active material;
equipping a substrate bottom side of the substrate facing away from the substrate top side with a second thermoelectrically active material;
applying an electrically conductive lower conducting layer to the second thermoelectrically active material;
introducing a plurality of upper receptacles, which extend in a longitudinal direction and are spaced apart from one another in a transverse direction, on the substrate top side, and a plurality of lower receptacles, which extend in the longitudinal direction and are spaced apart from one another in the transverse direction, on the substrate bottom side to produce an intermediate product, wherein the plurality of upper receptacles overlap, in the transverse direction in each case in an overlapping section extending in the transverse direction, with at least one of the plurality of lower receptacles that are adjacent in the transverse direction, and wherein the plurality of upper receptacles and the plurality of lower receptacles in each case remove an associated thermoelectrically active material such that a plurality of material sections that are adjacent in the transverse direction are formed;
applying an electrically conductive upper cover layer to an intermediate product top side of the intermediate product and an electrically conductive lower cover layer to an intermediate product bottom side of the intermediate product facing away from the intermediate product top side; and
introducing a plurality of upper clearances which extend in the longitudinal direction and are spaced apart from one another in the transverse direction on the intermediate product top side and a plurality of bottom clearances which extend in the longitudinal direction and are spaced apart from one another in the transverse direction on the intermediate product bottom side, wherein the plurality of upper clearances and the plurality of bottom clearances are respectively introduced in one of a plurality of overlapping sections;
wherein the plurality of upper clearances and the plurality of bottom clearances are introduced such that each removes an associated cover layer and enters the substrate, and each form a hollow space which separates the plurality of material sections that are adjacent in the transverse direction.

2. The method according to claim 1, wherein:
introducing the plurality of upper receptacles in each case includes removing a portion of the upper conducting layer and a portion of the first thermoelectrically active material to define a plurality of upper material sections spaced apart from one another in the transverse direction;
introducing the plurality of lower receptacles in each case includes removing a portion of the lower conducting layer and a portion of the second thermoelectrically active material to define a plurality of lower material sections spaced apart from one another in the transverse direction;
introducing the plurality of upper clearances, in each case, includes removing a portion of the upper cover layer and entering the substrate such that each forms the hollow space separating the plurality of material sections which are adjacent in the transverse direction; and
introducing the plurality of bottom clearances, in each case, includes removing a portion of the lower cover layer and entering the substrate such that each forms the hollow space separating the plurality of material sections which are adjacent in the transverse direction.

3. The method according to claim 1, further comprising dividing the substrate into at least two separate parts a respective part of which forms a thermoelectric converter, following the step of introducing the plurality of upper clearances, wherein dividing the substrate includes introducing at least one cut extending inclined with respect to the longitudinal direction.

4. The method according to claim 1, further comprising applying an oxidation protective layer on at least one of the upper conducting layer and the lower conducting layers.

5. The method according to claim 4, further comprising removing the protective layer prior to one of applying the upper cover layer and applying the lower cover layer to a side of the intermediate product with the protective layer.

6. The method according to claim 1, wherein at least one of equipping the substrate top side with the first thermoelectrically active material and equipping the substrate bottom side with the second thermoelectrically active material includes coating a respective thermoelectrically active materials onto the substrate.

7. The method according to claim 6, wherein the respective thermoelectrically active material is coated onto the substrate via vacuum-based deposition.

8. The method according to claim 1, wherein at least one of applying the upper conducting layer to the first thermoelectrically active material and applying the lower conducting layer to the second thermoelectrically active material includes coating a respective conducting layer onto an associated thermoelectrically active material.

9. The method according to claim 1, wherein at least one of applying the upper cover layer and applying the lower cover layer includes depositing a respective cover layer to a respective side of the intermediate product.

10. A thermoelectric converter produced according to a method comprising:
equipping a substrate top side of an electrically conductive substrate with a first thermoelectrically active material;
applying an electrically conductive upper conducting layer to the first thermoelectrically active material;
equipping a substrate bottom side of the substrate facing away from the substrate top side with a second thermoelectrically active material;
applying an electrically conductive lower conducting layer to the second thermoelectrically active material;
introducing a plurality of upper receptacles, which extend in a longitudinal direction and are spaced apart from one another in a transverse direction, on the substrate top side, and a plurality of lower receptacles, which extend in the longitudinal direction and spaced apart from one another in the transverse direction, on the substrate bottom side to produce an intermediate product, wherein the plurality of upper receptacles overlap, in the transverse direction in each case in an overlapping section extending in the transverse direction, with at least one of the plurality of lower receptacles that are adjacent in the transverse direction, and wherein the plurality of upper receptacles and the plurality of lower receptacles in each case remove an associated thermoelectrically active material such that a plurality of material sections that are adjacent in the transverse direction are formed;
applying an electrically conductive upper cover layer to an intermediate product top side of the intermediate product and an electrically conductive lower cover layer to an intermediate product bottom side of the intermediate product facing away from the intermediate product top side; and
introducing a plurality of upper clearances, which extend in the longitudinal direction and are spaced apart from one another in the transverse direction, on the intermediate product top side, and a plurality of bottom clearances, which extend in the longitudinal direction and are spaced apart from one another in the transverse direction, on the intermediate product bottom side, wherein the plurality of upper clearances and the plurality of bottom clearances are respectively introduced in one of a plurality of overlapping sections;
wherein the plurality of upper clearances and the plurality of bottom clearances are introduced such that each removes an associated cover layer and enters the substrate, and each form a hollow space which separates the plurality of material sections that are adjacent in the transverse direction.

11. The method according to claim 8, wherein the respective conducting layer is coated onto the respective thermoelectrically active material substrate via vacuum-based deposition.

12. The method according to claim 9, wherein the respective cover layer is deposited onto the respective side of the intermediate product via vacuum-based deposition.

13. The method according to claim 1, further comprising applying an oxidation protective layer on at least one of the upper conducting layer and the lower conducting layer.

14. The method according to claim 13, further comprising removing the protective layer prior to one of applying the upper cover layer and applying the lower cover layer to a side of the intermediate product with the protective layer.

15. The method according to claim 2, wherein at least one of equipping the substrate top side with the first thermoelectrically active material and equipping the substrate bottom side with the second thermoelectrically active material includes coating a respective thermoelectrically active material onto the substrate.

16. The method according to claim 15, wherein the respective thermoelectrically active material is coated onto the substrate via vacuum-based deposition.

17. The method according to claim 2, wherein at least one of applying the upper conducting layer to the first thermoelectrically active material and applying the lower conducting layer to the second thermoelectrically active material includes coating a respective conducting layer onto an associated thermoelectrically active material.

18. The method according to claim 2, wherein at least one of applying the upper cover layer and applying the lower cover layer includes depositing a respective cover layer to a respective side of the intermediate product.

19. A method for producing a thermoelectric converter, comprising:
equipping a substrate top side of an electrically conductive substrate with a first thermoelectrically active material;
applying an electrically conductive upper conducting layer to the first thermoelectrically active material;
equipping a substrate bottom side of the substrate facing away from the substrate top side with a second thermoelectrically active material;
applying an electrically conductive lower conducting layer to the second thermoelectrically active material;
producing an intermediate product via:
removing a plurality of portions of the upper conducting layer and the first thermoelectrically active material to define a plurality of upper receptacles and a plurality of upper material sections arranged on the substrate top side alternatively with one another in a longitudinal direction of the substrate, each of the plurality of upper material sections including a section of the upper conducting layer and a section of the first thermoelectrically active material; and
removing a plurality of portions of the lower conducting layer and the second thermoelectrically active material to define a plurality of lower receptacles and a plurality of lower material sections arranged on the substrate bottom side alternatively with one another in the longitudinal direction, each of the plurality of lower material sections including a section of the lower conducting layer and a section of the second thermoelectrically active material, wherein each lower receptacle of the plurality of lower receptacles and each upper receptacle of the plurality of upper receptacles are arranged overlapping at least one overlapping section of a plurality of overlapping sections, each of the plurality of overlapping sections overlapping one of the plurality of upper receptacles and one of the plurality of lower receptacles arranged adjacent one another in a transverse direction;
applying an electrically conductive upper cover layer to an intermediate product top side of the intermediate product such that the upper cover layer covers the plurality of upper material sections and fills the plurality of upper receptacles;
applying an electrically conductive lower cover layer to an intermediate product bottom side of the intermediate product facing away from the intermediate product top side such that the lower cover layer covers the plurality of lower material sections and fills the plurality of lower receptacles;
removing a portion of the upper cover layer, the substrate, and the lower cover layer disposed in at least one of the plurality of overlapping sections from the intermediate product top side to define a plurality of upper clearances each of which separate one of the plurality of upper material sections from one of the plurality of lower material sections; and
removing a portion of the lower cover layer, the substrate, and the upper cover layer disposed in at least another one of the plurality of overlapping sections from the intermediate product bottom side to define a plurality of lower clearances each of which separate one of the plurality of lower material sections from one of the plurality of upper material sections.

20. The method according to claim 19, further comprising dividing the substrate into at least two separate parts after introducing the plurality of upper clearances, a respective part of the two separate parts forming a thermoelectric converter, wherein dividing the substrate includes introducing at least one cut extending inclined with respect to the longitudinal direction.
